(19) United States
(12) Patent Application Publication
(10) Pub. No.: US 2010/0044743 A1
(43) Pub. Date: Feb. 25, 2010

(54) Flip chip light emitting diode with epitaxial strengthening layer and manufacturing method thereof

(76) Inventors: Cheng-Yi LIU, Jungli City (TW); You-Hsien Chang, Banciao City (TW); Shiaw-Tseh Chiang, Jhongli City (TW)

Correspondence Address: SINORICA, LLC, 2275 Research Blvd., Suite 500, ROCKVILLE, MD, 20850, US

(21) Appl. No.: 12/389,440

(22) Filed: Feb. 20, 2009

(30) Foreign Application Priority Data
Aug. 21, 2008 (TW) 097131945

(51) Int. Cl. H01L 33/00; H01L 21/50

(52) U.S. Cl. 257/99; 438/26; 257/E33.056; 257/E21.499

(57) ABSTRACT

A flip chip light emitting diode with an epitaxial strengthening layer and a manufacturing method thereof are revealed. The flip chip light emitting diode with an epitaxial strengthening layer includes an epitaxial structure connected with an epitaxial strengthening layer while the manufacturing method of the flip chip light emitting diode with an epitaxial strengthening layer is mainly to form an epitaxial strengthening layer on the epitaxial structure. Thus the epitaxial structure of the flip chip light emitting diode is strengthened so as to prevent breakage of the epitaxial structure while removing a substrate by laser assisted lift-off technique or other techniques. Moreover, the thermal expansion coefficient of the epitaxial strengthening layer matches well with thermal expansion coefficient of the epitaxial structure. Thus after being treated with cyclic heating, there is no stress caused by unmatched thermal expansion coefficient. Therefore, reliability of the flip chip light emitting diode with an epitaxial strengthening layer is improved.

### BACKGROUND OF THE INVENTION

1. Field of Invention

The present invention relates to a flip chip light emitting diode (LED) and a manufacturing method thereof, especially to a flip chip LED with an epitaxial strengthening layer and a manufacturing method thereof for strengthening epitaxial structure of the flip chip LED.

2. Description of Related Art

Refer from FIG. 1 to FIG. 3, a manufacturing method of a flip chip LED (light emitting diode) 3a available now includes a plurality of steps. Firstly, an epitaxial structure 12a is formed on a substrate 11a. Then a p type electrode 14a and a n type electrode 13a respectively are formed over the epitaxial structure 12a. Next the p type electrode 14a and the n type electrode 13a respectively are disposed with a metal bump 16a, 15a so as to from a light emitting diode 1a (as shown in FIG. 1). Later the light emitting diode 1a is reversely arranged on a submount 2a (as shown in FIG. 2). Then the substrate 11a is removed by laser assisted lift-off technique so as to get a flip chip LED 3a. Because the epitaxial structure 12a is a thin layer, it easily cracked while removing the substrate 11a by laser assisted lift-off technique, as shown in FIG. 3, and forming stress caused by cyclic heating. Although conventional encapsulating (underfilling) technique can solve breakage of the epitaxy layer (structure), the choke point of the technique is in that the underfill material requires both low thermal expansion coefficient and low viscosity coefficient. It's quite difficult to match the requirements because increasing ratio of inorganic filler makes thermal expansion coefficient of the material fall down while simultaneously the viscosity coefficient of the material increases. This leads to difficulties in selection of underfill material.

Thus there is a need to provide a flip chip LED and a manufacturing method thereof that strength the epitaxial structure of the flip chip LED. Thus the breakage of the epitaxial structure caused by removal of the substrate by laser assisted lift-off technique or other techniques is prevented so as to improve yield rate of the flip chip LED. Moreover, there is no need to consider viscosity of the material in material selection and development so that more materials are applied.

### SUMMARY OF THE INVENTION

Therefore it is primary object of the present invention to provide a flip chip LED with an epitaxial strengthening layer and a manufacturing method thereof in which the thermal expansion coefficient of the epitaxial strengthening layer matches well with the thermal expansion coefficient of the epitaxial structure so that the stress on the flip chip LED with an epitaxial strengthening layer caused by unmatched thermal expansion coefficient after cyclic heating can be avoided and the flip chip LED with an epitaxial strengthening layer will not be damaged. Thus reliability of the flip chip LED with an epitaxial strengthening layer is improved.

It is another object of the present invention to provide a flip chip light emitting diode (LED) with an epitaxial strengthening layer and a manufacturing method thereof that strengthen the epitaxial structure of the flip chip LED to prevent epitaxial breakage caused by removal of a substrate by laser assisted lift-off technique so as to increase yield rate of the flip chip LED.

A flip chip LED with an epitaxial strengthening layer consists of an epitaxial structure, a p-type electrode and a n-type electrode respectively connected on the P-type GaN and the N-type GaN of the epitaxial structure, two metal bumps respectively connected under the p-type electrode and the n-type electrode, a submount arranged under the two metal bumps, and an epitaxial strengthening layer disposed under the epitaxial structure.

A manufacturing method of a flip chip LED with an epitaxial strengthening layer includes the steps of: form an epitaxial structure on a substrate. Then a p-type electrode and a n-type electrode respectively are formed on two sides of the epitaxial structure. A metal bump is formed on the p-type electrode as well as the n-type electrode. Next form an epitaxial strengthening layer on the epitaxial structure and part of the two metal bumps project out of the epitaxial strengthening layer so as to form a LED with an epitaxial strengthening layer. Then the LED with an epitaxial strengthening layer is flipped and is joined with a submount. At last, remove the substrate to form a flip chip LED with an epitaxial strengthening layer.

Another manufacturing method of a flip chip LED with an epitaxial strengthening layer includes the steps of: form an epitaxial structure on a substrate. Then a p-type electrode and a n-type electrode respectively are formed on the epitaxial structure. Next form an epitaxial strengthening layer on the epitaxial structure and a metal bump mounting area is formed on the p-type electrode as well as the n-type electrode. A metal bump is formed on the metal bump mounting area of the p-type electrode as well as the n-type electrode and part of the two metal bumps project out of the epitaxial strengthening layer to form a LED with an epitaxial strengthening layer. The LED with an epitaxial strengthening layer is reversed and is assembled with a submount. At last, remove the substrate to get a flip chip LED with an epitaxial strengthening layer.

### BRIEF DESCRIPTION OF THE DRAWINGS

The structure and the technical means adopted by the present invention to achieve the above and other objects can be best understood by referring to the following detailed descriptions of the preferred embodiments and the accompanying drawings, wherein

FIG. 1 is a schematic drawing showing structure of a conventional flip chip LED during manufacturing processes;

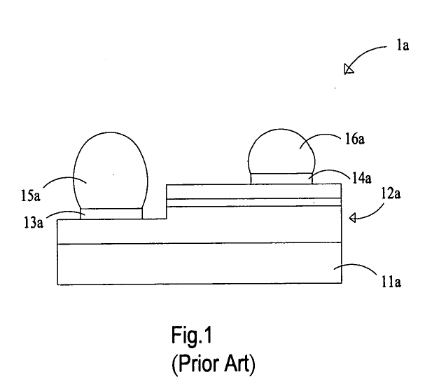

FIG. 2 is a schematic drawing showing structure of a conventional flip chip LED during manufacturing processes;

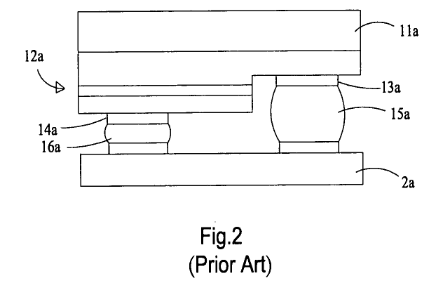

FIG. 3 is a schematic drawing showing structure of a conventional flip chip LED during manufacturing processes;

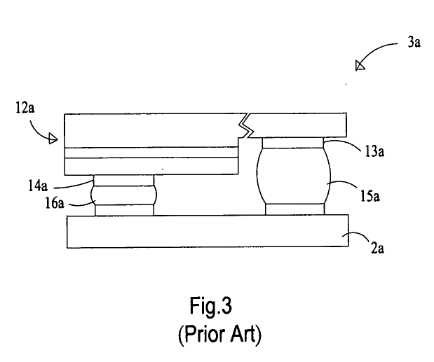

FIG. 4 is a schematic drawing showing structure of an embodiment of a flip chip LED with an epitaxial strengthening layer during manufacturing processes according to the present invention;

FIG. 5 is a schematic drawing showing structure of an embodiment of a flip chip LED with an epitaxial strengthening layer during manufacturing processes according to the present invention;

FIG. 6 is a schematic drawing showing structure of an embodiment of a flip chip LED with an epitaxial strengthening layer during manufacturing processes according to the present invention;

FIG. 7 is a schematic drawing showing structure of another embodiment of a flip chip LED with an epitaxial strengthening layer during manufacturing processes according to the present invention;

FIG. 8 is a schematic drawing showing structure of another embodiment of a flip chip LED with an epitaxial strengthening layer during manufacturing processes according to the present invention;

FIG. 9 is a schematic drawing showing structure of another embodiment of a flip chip LED with an epitaxial strengthening layer during manufacturing processes according to the present invention;

FIG. 10 is a schematic drawing showing structure of another embodiment of a flip chip LED with an epitaxial strengthening layer during manufacturing processes according to the present invention;

FIG. 11 is a flow chart showing steps of an embodiment of a manufacturing method of a flip chip LED with an epitaxial strengthening layer according to the present invention;

FIG. 12 is a flow chart showing steps of another embodiment of a manufacturing method of a flip chip LED with an epitaxial strengthening layer according to the present invention.

### DETAILED DESCRIPTION OF THE PREFERRED EMBODIMENT

A flip chip LED 3 with an epitaxial strengthening layer consists of an epitaxial structure 12, a p-type electrode 14 and a n-type electrode 13 respectively connected with two sides under the epitaxial structure 12, two metal bumps 16, 15 respectively arranged under the p-type electrode 14 and the n-type electrode 13, an epitaxial strengthening layer 17 arranged under the epitaxial structure 12, and two conductive contact layers 22, 21 on a submount 2 that are respectively connected with a bottom of the two metal bumps 16, 15. The two metal bumps 16, 15 project out of the epitaxial strengthening layer 17.

From top to bottom, the epitaxial structure 12 includes a n-type gallium nitride (GaN) layer 121, a light emitting layer 122 disposed under the n-type gallium nitride (GaN) layer 121, a p-type gallium nitride (GaN) layer 123 arranged under the light emitting layer 122. The n-type electrode 13 connects with the n-type gallium nitride (GaN) layer 121 and the p-type electrode 14 connects with the p-type gallium nitride (GaN) layer 123.

The thermal expansion coefficient of the epitaxial strengthening layer is 3-40 ppm/° C. while the thermal expansion coefficient of the epitaxial structure is 5-6 ppm/° C., matching each other quite well. Thus the compatibility of high temperature processes is improved and the yield rate of the flip chip LED is increased.

The material for the epitaxial strengthening layer is selected from epoxy, PMMA, acrylonitrile butadiene styrene copolymer, polymerethylmethacrylate, polysulfones, polyethersulfone, polyetherimides, polyimide, polyamideimide, polyphenylene sulfide, silicon-carbon thermosets, silicon oxide, aluminium oxide, silicon oxynitride (SiON), zinc oxide, hafnium oxide, titanium oxide, tantalum oxide, calcium chloride, zinc sulfide or their mixtures while the metal bump is made from gold, silver, copper, nickel gold alloy, tin-gold alloy, tin-copper alloy, or tin-silver alloy.

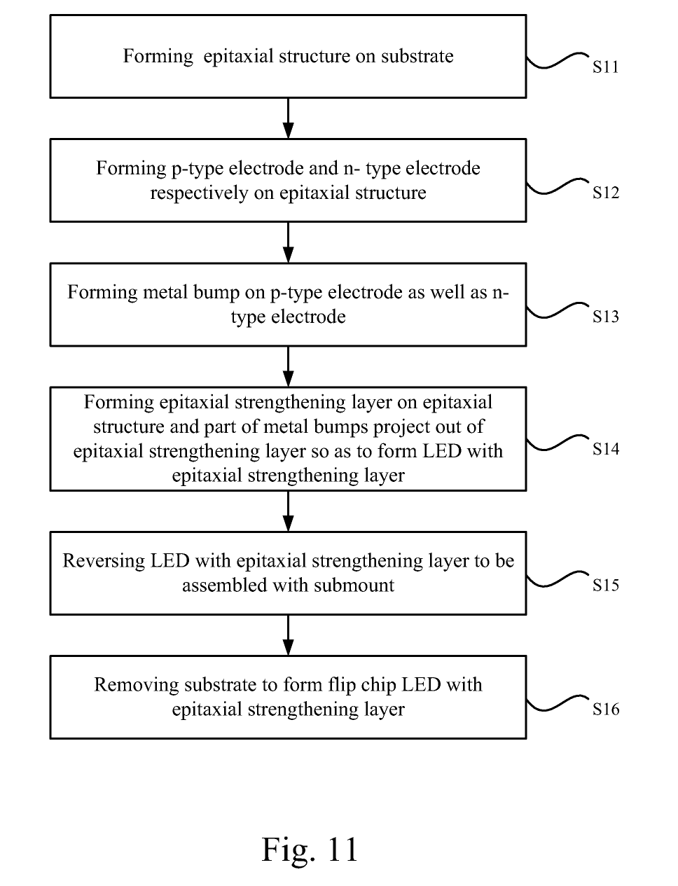

A manufacturing method of a flip chip LED 3 with epitaxial strengthening layer according to the present invention includes the following steps (as shown in FIG. 11):

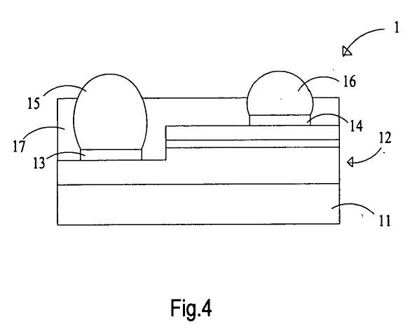

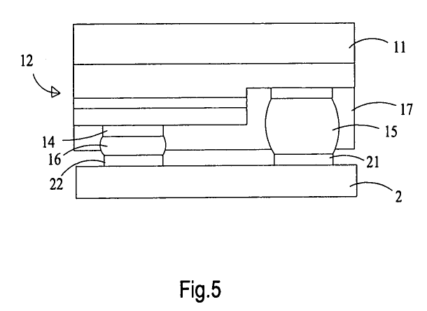

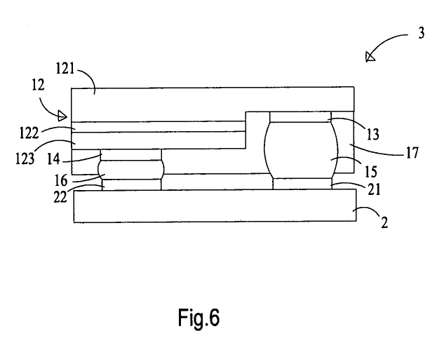

S11 form an epitaxial structure 12 on a substrate 11;
S12 a p-type electrode 14 and a n-type electrode 13 respectively are formed on the epitaxial structure 12;
S13 a metal bump 16, 15 is formed on the p-type electrode 14 as well as the n-type electrode 13 respectively;
S14 form an epitaxial strengthening layer 17 on the epitaxial structure 12 and part of the two metal bumps 16, 15 project out of the epitaxial strengthening layer 17 so as to form a LED with an epitaxial strengthening layer 1 (as shown in FIG. 4);
S15 reverse the LED with an epitaxial strengthening layer 1 and join it with a submount 2 (as shown in FIG. 5); and
S16 remove the substrate 11 to get a flip chip LED with an epitaxial strengthening layer 3 (as shown in FIG. 6).

The step S14 further includes a step of forming the epitaxial strengthening layer 17 on the epitaxial structure 12 by spin coating, spray coating, dry film lamination or printing. And after the step S14, the method further comprises a curing step that is run together with the step S15 at 150-300° C. Or after the curing step run simultaneously with the step S15 at 150-300° C., and then a post curing step is taken at 100-180° C.

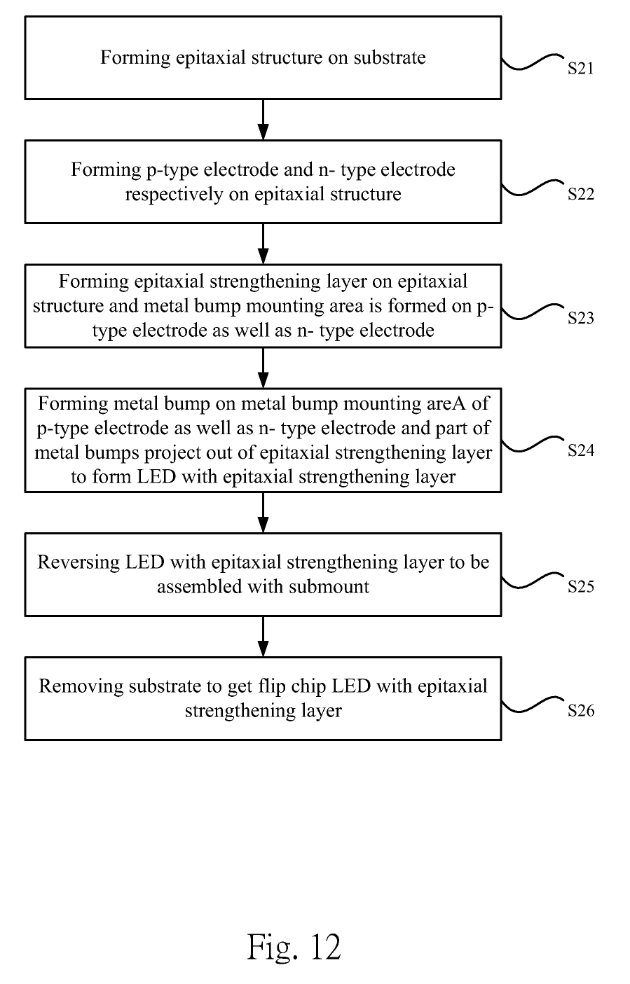

Another embodiment of the manufacturing method of a flip chip LED with an epitaxial strengthening layer according to the present invention includes the following steps (as shown in FIG. 12):

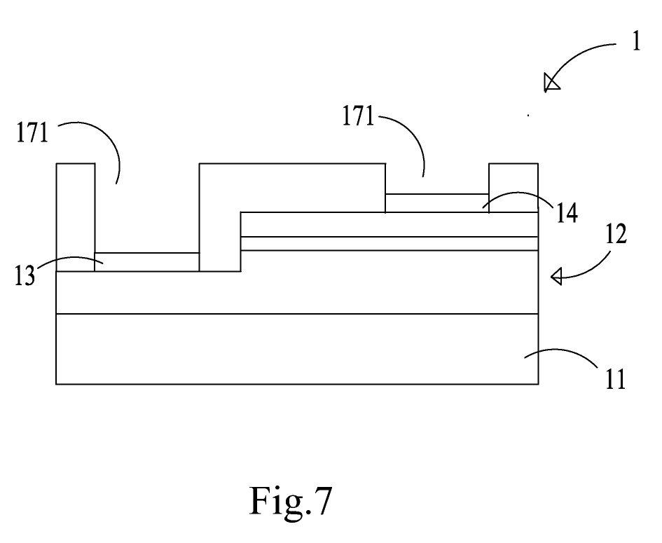

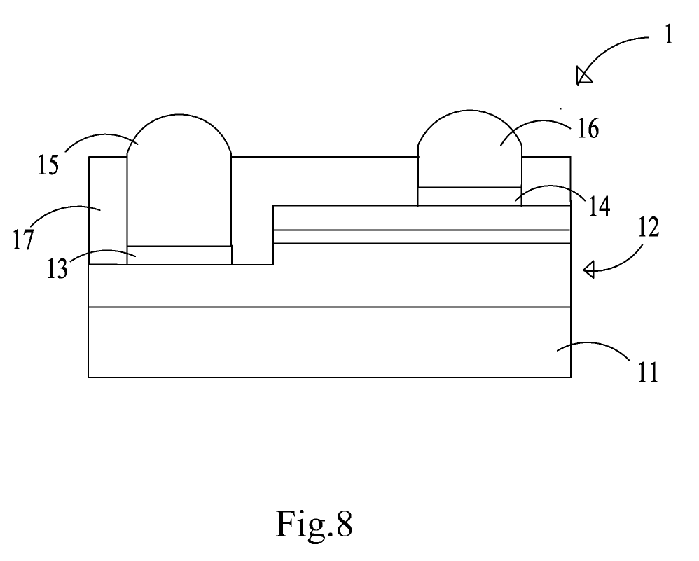

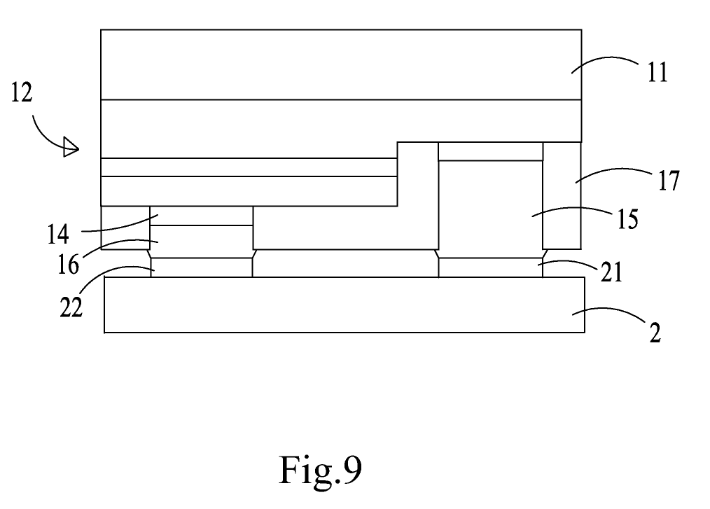

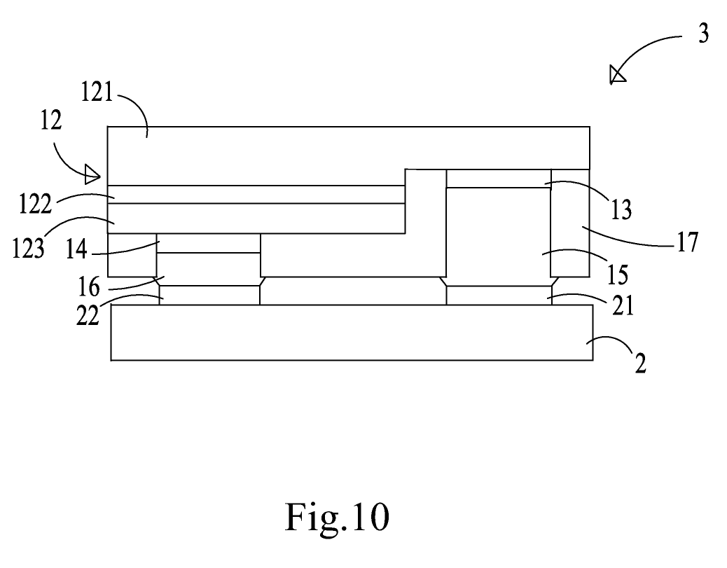

S21 form an epitaxial structure 12 on a substrate 11;
S22 a p-type electrode 14 and a n-type electrode 13 respectively are formed on the epitaxial structure 12;
S23 form an epitaxial strengthening layer 17 on the epitaxial structure 12 and a metal bump mounting area 171 is formed on the p-type electrode 14 as well as the n-type electrode 13 respectively (as shown in FIG. 7);
S24 a metal bump 16, 15 is formed on the metal bump mounting area 171 of the p-type electrode 14 as well as the n-type electrode 13 and part of the two metal bumps 16, 15 project out of the epitaxial strengthening layer 17 to form a LED with an epitaxial strengthening layer 1 (as shown in FIG. 8);
S25 reverse the LED with an epitaxial strengthening layer 1 and assemble it with a submount 2 (as shown in FIG. 9); and
S26 remove the substrate 11 to get a flip chip LED with an epitaxial strengthening layer 3 (as shown in FIG. 10).

The step S23 further includes a step of forming the epitaxial strengthening layer 17 on the epitaxial structure 12 by spin coating, spray coating, dry film lamination or printing.

And after the step S24, the method further comprises a curing step that is run together with the step of reversing the LED with epitaxial strengthening layer to be mounted with the submount at 150-300° C. Or after the curing step run with the step of reversing the LED with epitaxial strengthening layer to be mounted with the submount at 150-300° C., a post curing step is taken at 100-180° C.

### Embodiment

An epitaxial structure is grown on a transparent sapphire substrate by Metalorganic Chemical Vapor Deposition (MOCVD). The epitaxial structure includes a n-type GaN (gallium nitride) layer, a light emitting layer, and a p-type GaN (gallium-nitride) layer. The crystal is defined by photolithography technique. Part of the p-type GaN layer and the light emitting layer are removed by ICP dry etching and n-type GaN layer exposes. A p-type electrode and a n-type electrode are respectively formed on the p-type GaN layer and the n-type GaN layer. Then a tin-lead alloy bump is formed on the p-type electrode as well as the n-type electrode. The tin-lead alloy bump is made by photolithography in combination with sputtering, evaporation, or electroplating technique. After finishing the tin-lead alloy bump, an epitaxial strengthening layer is coated on the epitaxial structure while the tin-lead alloy bump projects out of the epitaxial strengthening layer to form a LED with epitaxial strengthening layer. The main function of the epitaxial strengthening layer is to strengthen the epitaxial structure after the sapphire substrate being removed by laser assisted lift-off technique and protect flip chip joint. The epitaxial strengthening layer is made from epoxy underfill with silicide filler manufactured by Ablestik (UF8826, components therein are business secret and are not learned). In this embodiment, the thermal expansion coefficient of the epitaxial strengthening layer is 40 ppm/° C. and the thermal expansion coefficient of the epitaxial structure ranges from 5 to 6 ppm/° C.

The LED with the epitaxial strengthening layer is reversed and welded on a silicon substrate with circuit design. The curing of the epitaxial strengthening layer is performed simultaneously with the welding process at 150-300° C. for 10 to 120 seconds.

Later, remove the sapphire substrate by laser assisted lift-off technique to get the flip chip LED with the epitaxial strengthening layer.

In summary, a flip chip LED with an epitaxial strengthening layer and a manufacturing method thereof according to the present invention have the following advantages:
1. The invention strengthens epitaxial structure of flip chip LED for preventing crack of the epitaxial structure caused by removal of the substrate by laser assisted lift-off technique or other techniques so as to improve yield rate of the flip chip LED.
2. The Coefficient of Thermal Expansion (CTE) of the epitaxial strengthening layer matches well with that of the epitaxial structure. Thus after being treated with cyclic heating, there is no stress caused by unmatched thermal expansion coefficient and the flip chip LED with an epitaxial strengthening layer will not be damaged. Therefore, reliability of the flip chip LED with an epitaxial strengthening layer is improved.
3. While selecting material for the epitaxial strengthening layer, there is no need to consider viscosity coefficient of the material. The preparation of the epitaxial strengthening layer overcomes the requirement for underfill material in low viscosity coefficient. Thus the present invention can be applied to industries.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A flip chip LED with an epitaxial strengthening layer comprising:
an epitaxial structure;
a p-type electrode and a n-type electrode respectively disposed under two sides of the epitaxial structure;
two metal bumps connected under the p-type electrode and the n-type electrode respectively, and
a submount arranged under the two metal bumps;
wherein an epitaxial strengthening layer is disposed under the epitaxial structure.

2. The device as claimed in claim 1, wherein the two metal bumps project out of the epitaxy structure.

3. The device as claimed in claim 1, wherein the epitaxy structure comprising from top to bottom:
a n-type gallium nitride (GaN) layer,
a light emitting layer arranged under the n-type gallium nitride layer; and
and a p-type gallium-nitride (GaN) layer disposed under the light emitting layer.

4. The device as claimed in claim 3, wherein the n-type electrode connects with the n-type gallium nitride (GaN) layer and the p-type electrode connects with the p-type gallium nitride (GaN) layer.

5. The device as claimed in claim 1, wherein thermal expansion coefficient of the epitaxial strengthening layer is 3-40 ppm/° C. and the thermal expansion coefficient of the epitaxial structure is 5-6 ppm/° C.; the thermal expansion coefficients match each other well.

6. The device as claimed in claim 1, wherein the epitaxial strengthening layer is made from epoxy, PMMA, acrylonitrile butadiene styrene copolymer, polymerethylmethacrylate, polysulfones, polyethersulfone, polyetherimides, polyimide, polyamideimide, polyphenylene sulfide, silicon-carbon thermosets, silicon oxide, aluminium oxide, silicon oxynitride (SiON), zinc oxide, hafnium oxide, titanium oxide, tantalum oxide, calcium chloride, zinc sulfide or their mixtures.

7. The device as claimed in claim 1, wherein the metal bump is made from gold, silver, copper, nickel gold alloy, tin-gold alloy, tin-copper alloy, or tin-silver alloy.

8. The device as claimed in claim 1, wherein the submount is disposed with two conductive contact layers that are connected with the two metal bumps respectively.

9. A manufacturing method of a flip chip light emitting diode with an epitaxial strengthening layer comprising the steps of:
forming an epitaxial structure on a substrate;
forming a p-type electrode and a n-type electrode respectively on the epitaxial structure;
forming a metal bump on the p-type electrode as well as the n-type electrode;
forming an epitaxial strengthening layer on the epitaxial structure and part of the two metal bumps project out of the epitaxial strengthening layer so as to form a LED with an epitaxial strengthening layer;
reversing the LED with an epitaxial strengthening layer to be assembled with a submount; and
removing the substrate to form a flip chip LED with an epitaxial strengthening layer.

10. The method as claimed is claim 9, wherein the step of forming an epitaxial strengthening layer on the epitaxial structure and part of the two metal bumps project out of the epitaxial strengthening layer so as to form a LED with an epitaxial strengthening layer further comprising a step of forming the epitaxial strengthening layer on the epitaxial structure by spin coating, spray coating, dry film lamination or printing.

11. The method as claimed is claim 9, wherein after the step of forming an epitaxial strengthening layer on the epitaxial structure and part of the two metal bumps project out of the epitaxial strengthening layer so as to form a LED with an epitaxial strengthening layer, the method further comprising a step of curing.

12. The method as claimed is claim 11, wherein the step of curing is run simultaneously with the step of reversing the LED with the epitaxial strengthening layer to be assembled with the submount at 150-300° C.

13. The method as claimed is claim 11, wherein after the step of curing being run simultaneously with the step of reversing the LED with the epitaxial strengthening layer to be assembled with the submount at 150-300° C., a post curing step is taken at 100-180° C.

14. The method as claimed is claim 9, wherein in the step of forming an epitaxial strengthening layer on the epitaxial structure and part of the two metal bumps project out of the epitaxial strengthening layer so as to form the LED with an epitaxial strengthening layer, thermal expansion coefficient of the epitaxial strengthening layer is 3-40 ppm/° C. and the thermal expansion coefficient of the epitaxial structure is 5-6 ppm/° C., matching each other well.

15. The method as claimed is claim 9, wherein in the step of forming an epitaxial strengthening layer on the epitaxial structure and part of the two metal bumps project out of the epitaxial strengthening layer, the epitaxial strengthening layer is made from epoxy, PMMA, acrylonitrile butadiene styrene copolymer, polymerethylmethacrylate, polysulfones, polyethersulfone, polyetherimides, polyimide, polyamideimide, polyphenylene sulfide, silicon-carbon thermosets, silicon oxide, aluminium oxide, silicon oxynitride (SiON), zinc oxide, hafnium oxide, titanium oxide, tantalum oxide, calcium chloride, zinc sulfide or their mixtures.

16. A manufacturing method of a flip chip LED with an epitaxial strengthening layer comprising the steps of:
forming an epitaxial structure on a substrate;
forming a p-type electrode and a n-type electrode respectively on the epitaxial structure;
forming an epitaxial strengthening layer on the epitaxial structure and a metal bump mounting area is formed on the p-type electrode as well as the n-type electrode;
forming a metal bump on the metal bump mounting area of the p-type electrode as well as the n-type electrode and part of the two metal bumps project out of the epitaxial strengthening layer to form a LED with an epitaxial strengthening layer;
reversing the LED with an epitaxial strengthening layer to be assembled with a submount; and
removing the substrate to get a flip chip LED with an epitaxial strengthening layer.

17. The method as claimed in claim 16, wherein the step of forming an epitaxial strengthening layer on the epitaxial structure and a metal bump mounting area is formed on the p-type electrode as well as the n-type electrode further comprising a step of forming the epitaxial strengthening layer on the epitaxial structure by spin coating, spray coating, dry film lamination or printing.

18. The method as claimed in claim 16, wherein after the step of forming a metal bump on the metal bump mounting area of the p-type electrode as well as the n-type electrode and part of the two metal bumps project out of the epitaxial strengthening layer to form a LED with an epitaxial strengthening layer, the method further comprising a step of curing.

19. The method as claimed in claim 18, wherein the step of curing is run simultaneously with the step of reversing the LED with the epitaxial strengthening layer to be assembled with the submount at 150-300° C.

20. The method as claimed in claim 18, wherein after the step of curing being run simultaneously with the step of reversing the LED with the epitaxial strengthening layer to be assembled with the submount at 150-300° C., a post curing step is taken at 100-180° C.

21. The method as claimed in claim 16, wherein in the step of forming an epitaxial strengthening layer on the epitaxial structure and a metal bump mounting area is formed on the p-type electrode as well as the n-type electrode, thermal expansion coefficient of the epitaxial strengthening layer is 3-40 ppm/° C. and the thermal expansion coefficient of the epitaxial structure is 5-6 ppm/° C., matching each other well

22. The device as claimed in claim 16, wherein in the step of forming an epitaxial strengthening layer on the epitaxial structure and a metal bump mounting area is formed on the p-type electrode as well as the n-type electrode, the epitaxial strengthening layer is made from epoxy, PMMA, acrylonitrile butadiene styrene copolymer, polymerethylmethacrylate, polysulfones, polyethersulfone, polyetherimides, polyimide, polyamideimide, polyphenylene sulfide, silicon-carbon thermosets, silicon oxide, aluminium oxide, silicon oxynitride (SiON), zinc oxide, hafnium oxide, titanium oxide, tantalum oxide, calcium chloride, zinc sulfide or their mixtures.
